(19) United States
(12) Patent Application Publication
(10) Pub. No.: US 2016/0040040 A1
(43) Pub. Date: Feb. 11, 2016

(54) Slurry for Selective Chemical Mechanical Polishing of Copper

(71) Applicant: Applied Materials, Inc., Santa Clara, CA (US)

(72) Inventors: Arup Purkayastha, Mumbai (IN); Prerna Goradia, Mumbai (IN); Ranga Rao Arnepalli, Veeravalli (IN); Robert Jan Visser, Menlo Park, CA (US); Rajeev Bajaj, Fremont, CA (US)

(21) Appl. No.: 14/456,356

(22) Filed: Aug. 11, 2014

(51) Int. Cl. C09G 1/02; H01L 21/321; B24B 37/04

(52) U.S. Cl. CPC C09G 1/02; B24B 37/044; H01L 21/3212

(57) ABSTRACT

A slurry for selective chemical mechanical polishing of a copper layer is disclosed. The slurry includes either porous zeolite abrasive particles of substantially homogeneous composition having an average pore diameter of approximately 0.1-6 nanometers or hexagonal boron nitride abrasive particles. The slurry also includes an organic complexing compound that is 0.1-25 wt. % of the slurry, an oxidizer that is 0.1-10 wt. % of the slurry, and a solvent. A chemical mechanical polishing method for using the slurry is also disclosed.

### TECHNICAL FIELD

The present invention relates generally to a slurry for chemical mechanical polishing, e.g., of a copper substrate.

### BACKGROUND

In the process of fabricating modern semiconductor integrated circuits (IC), it is often necessary to planarize the outer surface of the substrate. For example, planarization may be needed to polish away a conductive filler layer until the top surface of an underlying dielectric layer is exposed, leaving the conductive material between the raised pattern of the dielectric layer to form vias, plugs and lines that provide conductive paths between thin film circuits on the substrate. A barrier layer can be disposed between the dielectric layer and the conductive layer.

Chemical mechanical polishing (CMP) is one accepted method of planarization. This planarization method typically requires that a substrate be mounted on a carrier head. The exposed surface of the substrate is typically placed against a rotating polishing pad. The polishing pad can have a durable roughened surface. The carrier head provides a controllable load on the substrate to push it against the polishing pad while the substrate and polishing pad undergo relative motion.

An abrasive polishing slurry is typically supplied to the surface of the polishing pad. Commonly used slurries include silica or alumina particles.

### SUMMARY

One step in semiconductor IC device fabrication is polishing of the conductive layer until the underlying barrier layer or dielectric layer is exposed. One possible conductive layer is copper. Unfortunately, existing slurries for use in CMP do not give satisfactory CMP performance when polishing copper. For example, existing slurries may 1) have poor copper removal rates, 2) cause surface defects, such as excessive pitting, corrosion or roughness of the copper material, resulting in reduced device performance and device yield, 3) have difficulty achieving planarity, 4) result in poor IC electrical performance, and 5) have poor selectivity in that they remove not only the copper layer, but also the underlying barrier or dielectric layer.

A slurry composition that can provide superior copper removal rates and low levels of copper surface roughness can include abrasive particles of porous zeolite or hexagonal boron nitride. A slurry composition including abrasive particles of porous zeolite can also provide superior selectivity of copper removal as compared with removal of a Ta or TaN barrier layer. Also disclosed is a chemical mechanical polishing method for using the slurry.

In one aspect, a slurry for chemical mechanical polishing of a conductive copper layer includes porous zeolite abrasive particles of substantially homogeneous composition and having an average pore diameter of approximately 0.1-6 nanometers (synthetic aluminum silicate has an average pore diameter of 0.1-2 nanometers, while natural mesoporous aluminum silicate has an average pore diameter of about 4 nanometers). The slurry also includes an organic complexing compound for copper complexion that is 0.1-25 wt. % of the slurry, an oxidizer that is 0.1-10 wt. % of the slurry, and a solvent.

Implementations may include one or more of the following. The abrasive particles may have a particle size of 300-350 nanometers and may have a density of about 2.8 gm/cm³. The abrasive particles may be 9.5 wt. % Al₂O₃, 82.5 wt. % SiO₂, 8 wt. % Na₂O and 0.5 wt. % H₂O. The organic complexing compound may include glycine, imidazole, lactic acid, tartaric acid, citric acid or oxalic acid. The oxidizer may include hydrogen peroxide, monopersulfate, potassium permanganate, iodate, or dipersulfate. The slurry may include an inhibitor, such as benzotriazole. In some implementations, one slurry component can provide the functionality of both an inhibitor and an organic complexing compound. In some implementations, the slurry may not include an inhibitor. The slurry may have a pH of 8-13.

In another aspect, a slurry for chemical mechanical polishing of a conductive copper layer includes abrasive particles comprising a hexagonal polymorph of boron nitride. The slurry also includes an organic complexing compound for copper complexion that is 0.1-25 wt. % of the slurry, an oxidizer that is 0.1-10 wt. % of the slurry, and a solvent.

Implementations may include one or more of the following. The abrasive particles may have a particle size of 25-35 nanometers. The organic complexing compound may include glycine, imidazole, lactic acid, tartaric acid, citric acid or oxalic acid. The oxidizer may include hydrogen peroxide, monopersulfate, potassium permanganate, iodate, or dipersulfate. The slurry may include an inhibitor, such as benzotriazole. In some implementations, one slurry component can provide the functionality of both an inhibitor and an organic complexing compound. In some implementations, the slurry may not include an inhibitor. The slurry may have a pH of 8-13.

In another aspect, a method of polishing includes bringing a substrate having a copper conductive layer disposed over an underlying layer into contact with a polishing pad, supplying a slurry to the polishing pad, and generating relative motion between the substrate and the polishing pad to polish the copper conductive layer. The slurry has one of the compositions discussed above.

Advantages may include optionally one or more of the following. A slurry with porous abrasive zeolite particles can reduce copper ion induced defects on the copper surface. Without being limited to any particular theory, porous abrasive zeolite particles may be able to trap copper ions inside their pores and thus reduce copper ion induced defects. A slurry containing porous abrasive zeolite particles can also selectively remove copper as compared with removal of an underlying Ta or TaN barrier layer. A slurry with hexagonal boron nitride particles can polish copper with fewer surface defects. Again, without being limited to any particular theory, hexagonal boron nitride abrasive particles are soft, having a hardness of 1-2 on Mohs' hardness scale, and may be able to polish copper with fewer surface defects due to the softness imparted by the layered hexagonal structure of the boron nitride. The slurries can maintain other polishing criteria, such as polishing rate and planarization. Therefore, a copper conductive layer can be polished until an underlying barrier layer or dielectric layer is exposed with a lower level of surface roughness and while maintaining a satisfactory polishing rate and copper selectivity.

### BRIEF DESCRIPTION OF DRAWINGS

FIGS. 1A and 1B illustrate polishing of a substrate having a conductive layer over a patterned dielectric layer.

FIG. 2A shows a Transmission Electron Microscopy (TEM) image of porous abrasive zeolite particles. FIG. 2B shows a TEM image of abrasive hexagonal boron nitride particles.

### DETAILED DESCRIPTION

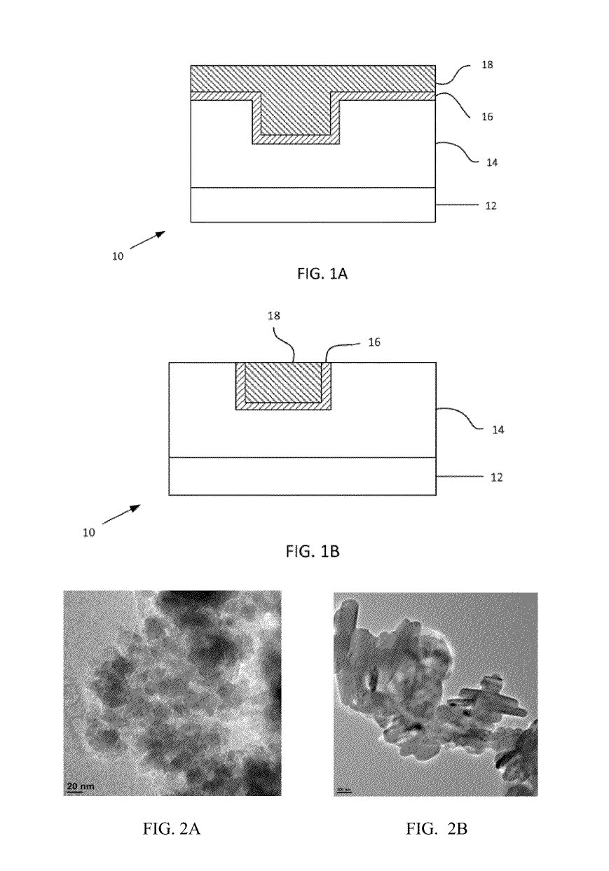

Referring to FIG. 1A, during an integrated circuit fabrication process, a substrate 10 can include a glass or semiconductor substrate 12, a patterned dielectric layer 14, and a conductive layer 18 disposed over the dielectric layer 14. A barrier layer 16 can be disposed between the dielectric layer 14 and the conductive layer 18. Additional unillustrated conductive and/or dielectric layers can be formed between the substrate 12 and the dielectric layer 14. The dielectric layer 14 can be an oxide, e.g., silicon oxide, or a low-k dielectric, e.g., a porous carbon-doped oxide. The conductive layer is copper.

As noted above, commercial slurries for the polishing of copper do not give satisfactory CMP performance because they have low copper removal rates and/or they result in high degrees of copper surface roughness. Commercial slurries also do not provide satisfactory selectivity of copper removal compared with removal of an underlying Ta or TaN barrier layer.

A proposed slurry chemistry that might address these problems can include (1) abrasive particles, (2) an organic complexing compound for copper ion complexion, (3) an oxidizer, and (4) a solvent such as water. The typical ranges for the wt. % of chemical components in the slurry are shown in Table 1.

TABLE 1

| SLURRY COMPONENT | WT. % OF THE SLURRY |
|---|---|
| Abrasive Particles | 1-3.5 |
| Organic Complexing Compound | 0.1-25 |
| Oxidizer | 0.1-10 |

The abrasive particles can be porous zeolite particles or hexagonal boron nitride particles. The abrasive particles can be of substantially homogenous composition, e.g., the particles consist only of the material, rather than being coated.

The surfaces of the zeolite particles have pores. The pores in the surfaces of the zeolite particles can have an average pore diameter of about 0.1-6 nanometers, e.g., 4 nanometers (synthetic aluminum silicate has an average pore diameter of 0.1-2 nanometers, while natural mesoporous aluminum silicate has an average pore diameter of about 4 nanometers). The zeolite particles can have a hardness of about 6 on the Mohs hardness scale and can have a density of about 2.8 gm/cm³. The porous zeolite particles can have a particle size of 300-350 nanometers, e.g., 310-340 nanometers. The porous zeolite particles may be 9.5 wt. % Al₂O₃, 82.5 wt. % SiO₂, 8 wt. % Na₂O and 0.5 wt. % H₂O and can have an inorganic chain structure. FIG. 2A shows a TEM image of abrasive porous zeolite particles.

With respect to the boron nitride particles, hexagonal refers to the hexagonal polymorph, i.e., a layered hexagonal lattice structure. The hexagonal boron nitride particles may have a particle size of 25-35 nanometers, e.g., 27-33 nanometers. The hexagonal boron nitride particles may have a hardness of 1-2 on the Mohs hardness scale and may have a density of 2.1 gm/cm³. FIG. 2B shows a TEM image of abrasive hexagonal boron nitride particles.

The organic complexing compound is a substance capable of forming a complex compound with copper metal ions. Thus, the complexing compound forms coordinate bonds with copper ions. The organic complexing compound can be imidazole and/or polyethyleneimine. However, other organic acids, such as glycine, lactic acid, tartaric acid, citric acid or oxalic acid can be used. The organic complexing compound can be 0.1-25 wt. % of the slurry, e.g., 0.2-15 wt. % of the slurry or 0.4-1.3 wt. % of the slurry.

The oxidizer can be hydrogen peroxide. However, other oxidizers, such as monopersulfate, potassium permanganate, iodate, or dipersulfate can be used. The oxidizer can be 0.1-10 wt. % of the slurry, e.g., 0.01-9 wt. % of the slurry or 0.1-1.3 wt. % of the slurry.

The slurry can also include a copper corrosion inhibitor. The corrosion inhibitor can be 0.001-6 wt. % of the slurry. The copper corrosion inhibitor may be benzotriazole. Alternatively, the slurry may not include a copper corrosion inhibitor. In some implementations, one slurry component can provide the functionality of both a copper corrosion inhibitor and an organic complexing compound. For example, polyethyleneimine may act as both a copper corrosion inhibitor and an organic complexing compound.

The pH of the slurry may be in the range of 8-13, e.g., 10-11. If necessary, the slurry can also include a pH adjustor to set the pH of the slurry. The pH adjustor can be KOH.

The slurries described above can polish a copper conductive layer until an underlying barrier layer or dielectric layer is exposed with a lower level of surface roughness and while maintaining a satisfactory polishing rate and satisfactory copper selectivity. For example, the root-mean-square roughness of the copper surface can be 0.738 nanometers after post CMP cleaning and as determined by Atomic Force Microscopy, while the copper removal rate can be 86 nanometers every minute. As another example, the root-mean-square roughness of the copper surface can be 2.069 nanometers after post CMP cleaning and as determined by Atomic Force Microscopy, while the copper removal rate can be 132 nanometers every minute. With respect to copper selectivity, the ratio of the conductive copper layer removed to Ta barrier layer removed can be 43 (as opposed to a ratio of only 6 in commercial slurries that use amorphous silica as an abrasive). The ratio of conductive copper layer removed to TaN barrier layer removed can be 86 (as opposed to a ratio of only 7.14 in commercial slurries that use amorphous silica as an abrasive).

In some implementations, the abrasive particles described above can be embedded in a polishing pad, rather than contained in a slurry. In this case, the other liquid components, e.g., the organic complexing compound and the oxidizer, can be provided in a polishing liquid, e.g., an abrasive-free polishing liquid, that is supplied to the polishing pad. The abrasive particles can be embedded in a polymer matrix of a polishing layer e.g., to provide a fixed abrasive polishing pad. In general, as polishing progresses, the polymer matrix can wear away, releasing the abrasive particles.

### EXAMPLE 1

Bulk polishing of a copper conductive layer over a barrier layer or a dielectric layer can be conducted using a polishing system. For example, polishing can be performed using a microporous polyurethane pad. Polishing can be conducted at a platen and carrier head rotation rate of 80 rpm, a down force on the wafer of 15 lbs, and a slurry flow rate of 80-90 ml/min. Polishing can be conducted using a slurry having the following components:

3.5 wt. % porous zeolite abrasive particles having an average pore diameter of approximately 4 nanometers;

0.4 wt. % imidazole;

0.33 wt. % polyethyleneimine;

1.3 wt. % 30 wt. % hydrogen peroxide.

### EXAMPLE 2

Bulk polishing of a copper conductive layer over a barrier layer or a dielectric layer can be conducted using a polishing system. For example, polishing can be performed using a microporous polyurethane pad. Polishing can be conducted at a platen and carrier head rotation rate of 80 rpm, a down force of 15 lbs, and a slurry flow rate of 80-90 ml/min. Polishing can be conducted using a slurry having the following components:

3.5 wt. % hexagonal boron nitride abrasive particles;

0.8 wt. % imidazole;

0.6 wt. % polyethyleneimine;

1.3 wt. % 30 wt. % hydrogen peroxide.

### EXAMPLE 3

Bulk polishing of a copper conductive layer over a barrier layer or a dielectric layer can be conducted using a polishing system. For example, polishing can be performed using a microporous polyurethane pad. Polishing can be conducted at a platen and carrier head rotation rate of 80 rpm, a down force of 15 lbs, and a slurry flow rate of 80-90 ml/min. Polishing can be conducted using a slurry having the following components:

3 wt. % porous zeolite abrasive particles having an average pore diameter of approximately 4 nanometers;

0.25 wt. % imidazole;

1 wt. % 30 wt. % hydrogen peroxide.

The above described slurries can be used in a variety of polishing systems. Either the polishing pad, or the carrier head, or both can move to provide relative motion between the polishing surface and the substrate. The polishing pad can be a circular (or some other shape) pad secured to the platen, or a continuous or roll-to-roll belt.

The substrate can be, for example, a product substrate (e.g., which includes multiple memory or processor dies), a test substrate, a bare substrate, or a gating substrate. The substrate can be at various stages of integrated circuit fabrication, e.g., it can include one or more deposited and/or patterned layers. The term substrate can include circular disks and rectangular sheets.

What is claimed is:

1. A slurry for chemical mechanical polishing of a copper layer, comprising:
porous zeolite abrasive particles of substantially homogenous composition, the porous zeolite abrasive particles having pores with an average pore diameter of approximately 0.1-6 nanometers;
an organic complexing compound for copper ion complexion, the organic complexing compound being 0.1-25 wt. % of the slurry;
an oxidizer, the oxidizer being 0.1-10 wt. % of the slurry; and
a solvent.

2. The slurry of claim 1, wherein the abrasive particles have a particle size of 300 to 350 nanometers.

3. The slurry of claim 1, wherein the abrasive particles have a density of about 2.8 gm/cm3.

4. The slurry of claim 1, wherein the abrasive particles have 9.5 wt. % Al2O3, 82.5 wt. % SiO2, 8 wt. % Na2O and 0.5 wt. % H₂O.

5. The slurry of claim 1, wherein the slurry does not include a corrosion inhibitor.

6. The slurry of claim 1, wherein the oxidizer comprises hydrogen peroxide, monopersulfate, potassium permanganate, iodate, or dipersulfate.

7. The slurry of claim 1, wherein the organic complexing compound comprises polyethyleneimine, glycine, imidazole, lactic acid, tartaric acid, citric acid or oxalic acid.

8. The slurry of claim 1, wherein the organic complexing compound comprises polyethyleneimine and imidazole.

9. The slurry of claim 8, wherein the oxidizer comprises hydrogen peroxide.

10. The slurry of claim 9, wherein the slurry has a pH of 8-13.

11. A slurry for chemical mechanical polishing of a copper layer, comprising:
abrasive particles comprising a hexagonal polymorph of boron nitride;
an organic complexing compound for copper ion complexion, the organic complexing compound being 0.1-25 wt. % of the slurry;
an oxidizer, the oxidizer being 0.1-10 wt. % of the slurry; and
a solvent.

12. The slurry of claim 11, wherein the abrasive particles have a particle size of 25-35 nanometers.

13. The slurry of claim 11, wherein the slurry does not include a corrosion inhibitor.

14. The slurry of claim 11, wherein the organic complexing compound comprises polyethyleneimine, glycine, imidazole, lactic acid, tartaric acid, citric acid or oxalic acid.

15. The slurry of claim 11, wherein the oxidizer comprises hydrogen peroxide, monopersulfate, potassium permanganate, iodate, or dipersulfate.

16. The slurry of claim 11, wherein the organic complexing compound comprises polyethyleneimine and imidazole.

17. The slurry of claim 16, wherein the oxidizer comprises hydrogen peroxide.

18. The slurry of claim 17, wherein the slurry has a pH of 8-13.

19. A method of polishing, comprising:
bringing a substrate having a copper conductive layer disposed over an underlying layer into contact with a polishing pad;
supplying a slurry to the polishing pad, wherein the slurry includes porous zeolite abrasive particles of substantially homogeneous composition and having an average pore diameter of approximately 0.1-6 nanometers, an organic complexing compound for copper ion complexion that is 0.1-25 wt. % of the slurry, an oxidizer that is 0.1-10 wt. % of the slurry, and a solvent; and
generating relative motion between the substrate and the polishing pad to polish the copper conductive layer.

20. A method of polishing, comprising:
bringing a substrate having a copper conductive layer disposed over an underlying layer into contact with a polishing pad;
supplying a slurry to the polishing pad, wherein the slurry includes abrasive particles comprising a hexagonal polymorph of boron nitride, wherein the slurry also includes an organic complexing compound for copper ion complexion that is 0.1-25 wt. % of the slurry, an oxidizer that is 0.1-10 wt. % of the slurry, and a solvent; and
generating relative motion between the substrate and the polishing pad to polish the copper conductive layer.
